(19) United States
(12) Patent Application Publication
(10) Pub. No.: US 2008/0211039 A1
(43) Pub. Date: Sep. 4, 2008

(54) Nonvolatile memory devices having metal silicide nanocrystals, methods of forming metal silicide nanocrystals, and methods of forming nonvolatile memory devices having metal silicide nanocrystals

(75) Inventors: Xiaofeng Wang, Gyeonggi-do (KR); Eun-Ji Jung, Gyeonggi-do (KR); In-Seok Yeo, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/999,704

(22) Filed: Dec. 6, 2007

(30) Foreign Application Priority Data
Dec. 7, 2006 (KR) 10-2006-0124069

(51) Int. Cl. H01L 29/78; H01L 21/44

(52) U.S. Cl. 257/412; 438/683; 257/E21.476; 257/E29.255

(57) ABSTRACT

A nonvolatile memory device includes a semiconductor substrate. A charge storage insulating film containing metal silicide nanocrystals is on the substrate. A gate electrode is on the charge storage insulating film. Related methods of forming metal silicide nanocrystals, and methods of forming nonvolatile memory devices including metal silicide nanocrystals, are also disclosed.

### CROSS-REFERENCE TO RELATED PATENT APPLICATION

This application claims the benefit of and priority to Korean Patent Application No. 10-2006-0124069, filed on Dec. 7, 2006, in the Korean Intellectual Property Office, the disclosure of which is incorporated herein in its entirety by reference.

### BACKGROUND

1. Field of the Invention

The present invention relates to nonvolatile memory devices and methods of forming nonvolatile memory devices, and more particularly, to nonvolatile memory devices including nanocrystals, methods of forming nanocrystals, and methods of forming nonvolatile memory devices.

2. Description of the Related Art

In recent years, efforts to reduce feature sizes and to lower write voltages and erase voltages of nonvolatile memory devices have continued as the integration level of nonvolatile memory devices has accelerated. For example, some efforts have focused on next-generation nonvolatile memory devices that use nanocrystals as a charge storage medium, i.e. nanocrystal nonvolatile memory devices.

Existing nanocrystal nonvolatile memory devices typically employ silicon nanocrystals or metal nanocrystals. Since the size of silicon nanocrystals is very small, silicon nanocrystals may be advantageous for achieving nonvolatile memory devices with small features. However, capacitive coupling of silicon nanocrystals with a control gate electrode or a channel is low. Thus, an operating voltage of a nonvolatile memory device which employs silicon nanocrystals may be relatively high. In comparison, an operating voltage of a nonvolatile memory device which employs metal nanocrystals may be relatively low, but the size of metal nanocrystals is relatively large, so that it may be difficult to achieve small feature sizes in nonvolatile memory devices that employ metal nanocrystals. Furthermore, the interface between a metal nanocrystal and a silicon oxide film may be unstable.

### SUMMARY

Embodiments of the invention provide methods of forming a nonvolatile memory device, including forming a silicon-containing insulating film on a substrate, forming a metal film on the silicon-containing insulating film, and thermally treating the silicon-containing insulating film on which the metal film is formed to thereby form metal silicide nanocrystals in the silicon-containing insulating film. The metal film is removed from the silicon-containing insulating film to thereby expose at least a portion of the silicon-containing insulating film, and a gate electrode film is formed on the exposed silicon-containing insulating film.

The methods may further include forming a tunnel insulating film on the substrate before forming the silicon-containing insulating film. The methods may further include forming a blocking insulating film on the exposed portion of the silicon-containing insulating film before forming the gate electrode film.

Thermally treating the silicon-containing insulating film may include a low-temperature treatment and a high-temperature treatment. The low-temperature treatment may be performed at a temperature of from about 300° C. to about 500° C., and the high-temperature treatment may be performed at a temperature of from about 600° C. to about 800° C.

The methods may further include forming a capping layer on the metal film before thermally treating the silicon-containing insulating film.

The methods may further include, before forming the gate electrode film, forming a second silicon-containing insulating film on the first silicon-containing insulating film, forming a second metal film on the second silicon-containing insulating film, thermally treating the substrate including the second metal film to thereby form second silicide nanocrystals in the second silicon-containing insulating film, and removing the second metal film to thereby expose portions of the second silicon-containing insulating film.

A capping layer may be formed on the second metal film before thermally treating the substrate including the second metal film.

The silicon-containing insulating film may include a silicon rich oxide film (SRO) and/or a silicon rich nitride film (SRN). The metal film may include tantalum, molybdenum, nickel, titanium, cobalt, and/or tungsten.

Methods of forming metal silicide nanocrystals according to some embodiments of the invention include forming a silicon-containing insulating film on a substrate, forming a metal film on the silicon-containing insulating film, and thermally treating the substrate including the metal film to thereby form metal silicide nanocrystals in the silicon-containing insulating film.

Thermally treating the silicon-containing insulating film may include a low-temperature treatment and a high-temperature treatment. The low-temperature treatment may be performed at a temperature of from about 300° C. to about 500° C., and the high-temperature treatment may be performed at a temperature of from about 600° C. to about 800° C.

The methods may further include forming a capping layer on the metal film before thermally treating the silicon-containing insulating film.

The silicon-containing insulating film may include a silicon rich oxide film and/or a silicon rich nitride film. The metal film may include tantalum, molybdenum, nickel, titanium, cobalt, and/or tungsten.

A nonvolatile memory device according to some embodiments includes a semiconductor substrate, a charge storage insulating film that contains metal silicide nanocrystals on the semiconductor substrate, and a gate electrode on the first charge storage insulating film.

The nonvolatile memory device may further include a tunnel insulating film between the charge storage insulating film and the substrate, and/or a blocking insulating film between the gate electrode and the charge storage insulating film.

The device may further include a second charge storage insulating film containing second metal silicide nanocrystals between the gate electrode and the charge storage insulating film. The charge storage insulating film may include a silicon rich oxide film and/or a silicon rich nitride film.

The metal silicide may include tantalum silicide, molybdenum silicide, nickel silicide, titanium silicide, cobalt silicide, and/or tungsten silicide.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1A through FIG. 1D are cross-sectional views illustrating methods of forming nonvolatile memory devices according to some embodiments of the present invention;

FIG. 2A through FIG. 2F are cross-sectional views illustrating methods of forming nonvolatile memory devices according to further embodiments of the present invention;

FIG. 3A and FIG. 3B are TEM photographs showing a gate pattern of nonvolatile memory device according to some embodiments of the present invention; and

FIG. 4 is a graph showing a capacitance-voltage (C-V) curve in a MOS capacitor structure of a nonvolatile memory device according to some embodiments of the present invention.

### DETAILED DESCRIPTION OF EMBODIMENTS OF THE INVENTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

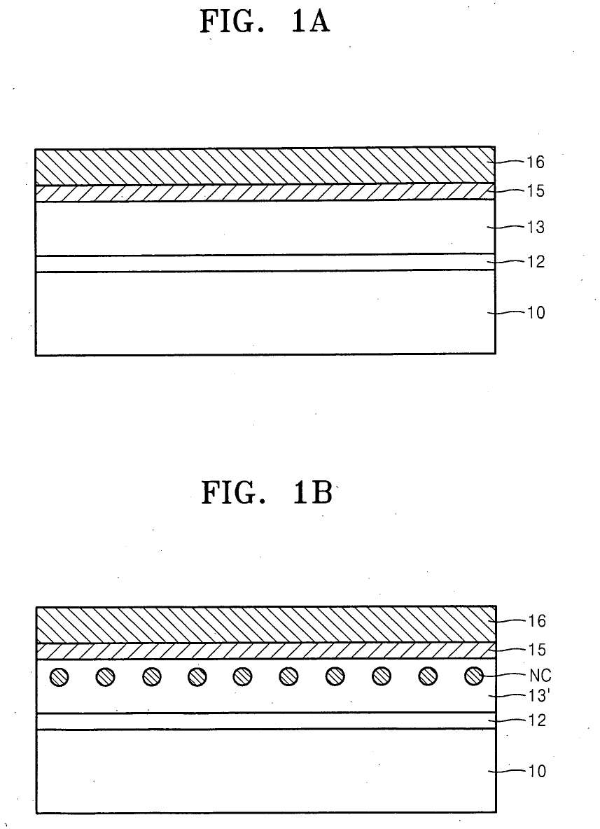

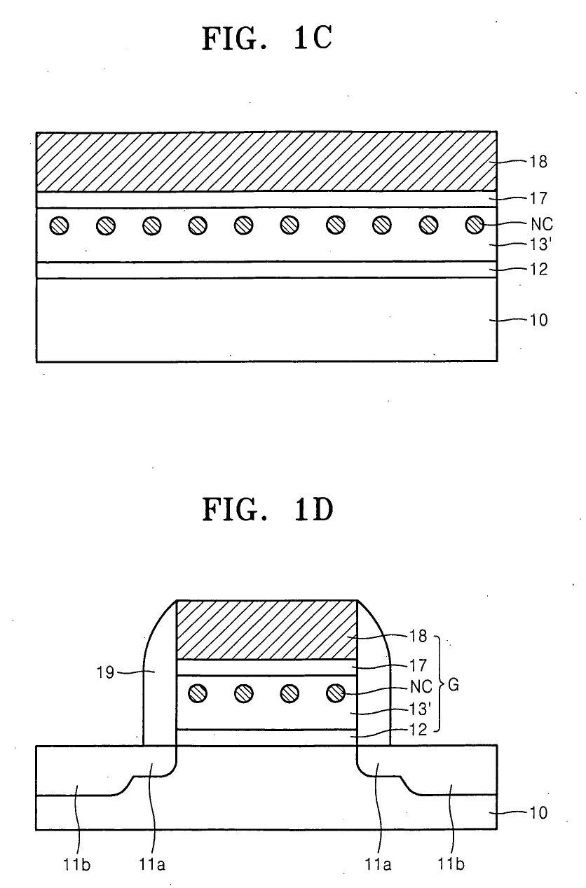

FIG. 1A through FIG. 1D are cross-sectional views illustrating methods of forming nonvolatile memory devices according to some embodiments of the present invention.

Referring FIG. 1A, an optional tunnel insulating film 12 is formed on a semiconductor substrate 10. The tunnel insulating film 12 may include a silicon oxide film, a silicon oxynitride film, a hafnium oxide film, an aluminium oxide film and/or a composite film including one or more of the foregoing. In some embodiments, the tunnel insulating film 12 may include a dry thermal oxide film.

A silicon-containing insulating film 13 is formed on the tunnel insulating film 12. The silicon-containing insulating film 13 may be a silicon rich insulating film (SRI). The silicon rich insulating film may contain a non-stoichiometric proportion of silicon particles in an insulating film, and may include a silicon rich oxide film (SRO) and/or a silicon rich nitride film (SRN). A silicon rich oxide film can be defined as SiO_{X} in which X<2. The silicon-containing insulating film 13 may be formed, for example, using chemical vapor deposition (CVD) and/or atomic layer deposition (ALD). The silicon-containing insulating film 13 may be formed so as to have a thickness of about 4 nm to about 10 nm, but the thickness is not limited thereto.

A metal film 15 is formed on the silicon-containing insulating film 13. The metal film 15 may include a high-melting-point metal film, such as a tungsten (W) film, a titanium (Ti) film, a cobalt (Co) film, a nickel (Ni) film, a tantalum (Ta) film, a molybdenum (Mo) film and/or an alloy including one or more of the foregoing. In particular embodiments, the metal film 15 may include a cobalt (Co) film. The metal film 15 may be formed, for example, using physical vapor deposition, chemical vapor deposition and/or atomic layer deposition, and may be formed to have a thickness of about 20 nm, although other thicknesses may be formed.

A capping layer 16 may be formed on the metal film 15. The capping layer 16 may reduce or prevent an oxidation of the metal film 15. In order to reduce or prevent the oxidation of the metal film 15, the metal film 15 and the capping layer 16 can be formed sequentially in situ without vacuum breaking. The capping layer 16 may include a titanium film, a titanium nitride film and/or a composite film including one or more of the foregoing.

Referring to FIG. 1B, the structure including the substrate 10, the optional tunnel insulating film 12, the silicon-containing insulating film 13, the metal film 15 and the capping layer 16 is subjected to a low-temperature thermal treatment. As a result of the low temperature thermal treatment, metal from the metal film 15 diffuses into the silicon-containing insulating film 13. In addition, the silicon-containing insulating film 13 may be hardened, so that metal diffusion paths may be closed. Accordingly, diffused metal is positioned at portions of the silicon-containing insulating film 13. The silicon-containing insulating film 13 may retard the diffusion of metal, so that the speed of diffusion of metal in the silicon-containing insulating film 13 may be very slow compared to the speed of the diffusion of metal in, for example, a silicon film.

The low-temperature thermal treatment can be performed, for example, using a furnace method and/or a rapid thermal process (RTP) method. The low-temperature thermal treatment can be performed under an inert gas atmosphere, such as nitrogen, argon or helium, at a temperature of about 300° C. to about 500° C., and in some embodiments at a temperature of about 300° C. to about 460° C.

After the low-temperature thermal treatment, the structure is subjected to a high-temperature thermal treatment at a higher temperature than that of the low-temperature thermal treatment. The temperature of the high-temperature thermal treatment is higher than the temperature of the low-temperature thermal treatment. As a result of the high-temperature thermal treatment, metal that is diffused into the silicon-containing insulating film 13 reacts with silicon in the silicon-containing insulating film 13 to form metal silicide nanocrystals (NC). The high-temperature thermal treatment may also be performed using a furnace method and/or a rapid thermal process method. The high-temperature thermal treatment can be performed under an inert gas atmosphere, such as nitrogen, argon or helium, at a temperature of about 600° C. to about 800° C.

The vertical distribution of the metal silicide nanocrystals (NC) can be affected by the thickness of the silicon-containing insulating film 13 and/or the conditions of the low-temperature thermal treatment. The metal silicide nanocrystals (NC) thus formed may be monocrystalline. A diffusion speed of metal in the silicon-containing insulating film 13 may be very slow, so that an amount of metal that is diffused into the silicon-containing insulating film 13 may be small, while the amount of silicon is rich, as described above. When the metal film 15 includes cobalt (Co), the metal silicide nanocrystals (NC) may include CoSi₂ nanocrystals. CoSi₂ has a lower resistivity and is thermally and chemically stable compared with other cobalt silicides, such as CoSi and Co₂Si. In addition, the shape of the metal silicide nanocrystals (NC) may be approximately spherical, and the size of the nanocrystals may be very fine, i.e., on the order of about 2 nm to about 4 nm in diameter.

The silicon-containing insulating film 13 that contains the metal silicide nanocrystals (NC) may function as a charge storage insulating film 13′.

Referring to FIG. 1C, the capping layer (as indicated at reference numeral 16 in FIG. 1B) and the metal film (as indicated at reference numeral 15 in FIG. 1B) are removed to thereby expose the charge storage insulating film 13′. The capping layer 16 and the metal film 15 can be removed, for example, using wet etching.

In some embodiments, the high-temperature thermal treatment can be carried out after removing the capping layer 16 and the metal film 15.

A blocking insulating film 17 is formed on the exposed charge storage insulating film 13′. The blocking insulating film 17 may include a silicon oxide film, a silicon oxynitride film, a hafnium oxide film, an aluminium oxide film and/or a composite film including any of the foregoing.

A gate conductive film 18 is formed on the blocking insulating film 17. The gate conductive film 18 may include a polysilicon film and/or a laminated film including polysilicon and metal silicide films.

Referring to FIG. 1D, the gate conductive film 18, the blocking insulating film 17, the charge storage insulating film 13′, and the optional tunnel insulating film 12 may be patterned to form a gate pattern (G).

N-type and/or p-type impurities may be implanted at a relatively low concentration into the substrate 10 using the gate pattern (G) as a mask so that lightly doped drain (LDD) regions 11a can be formed. Thereafter, a spacer insulating film is formed on the gate pattern (G), and the spacer insulating film is anisotropically etched so that an insulating spacer 19 is formed on side walls of the gate pattern (G). Impurities having the same conductivity as the impurities used to form the LDD regions 11a in the substrate 10 using the gate pattern (G) and the insulating spacer 19 as a mask are implanted at a higher concentration to thereby form source/drain regions 11b. A region between the LDD regions 11a is defined as a channel region.

As illustrated in FIG. 1D, a nonvolatile memory device according to embodiments of the present invention includes a charge storage insulating film 13′ containing metal silicide nanocrystals (NC) positioned on a semiconductor substrate 10. The charge storage insulating film 13′ may include a silicon-containing insulating film, and more particularly, may include a silicon rich insulating film. The silicon rich insulating film may include a silicon rich oxide (SRO) film and/or a silicon rich nitride (SRN) film. The metal silicide may include tantalum silicide, molybdenum silicide, nickel silicide, titanium silicide, cobalt silicide, tungsten silicide and/or a combination of any of the foregoing. In some embodiments, the metal silicide may include cobalt silicide (CoSi₂), which may have low resistivity and which may be thermally and chemically stable. The metal silicide nanocrystals (NC) are positioned in a portion of the charge storage insulating film 13′. The metal silicide nanocrystals (NC) may be a monocrystalline, may be spherical in shape, and/or may have a size of about 2 nm to about 4 nm in diameter.

A gate electrode 18 is positioned on the charge storage insulating film 13′. The gate electrode 18 may include a polysilicon film and/or a laminated film including polysilicon and metal silicide films.

An optional tunnel insulating film 12 may be positioned between the charge storage insulating film 13′ and the substrate 10. The tunnel insulating film 12 may include a silicon oxide film, a silicon oxynitride film, a hafnium oxide film, an aluminium oxide film, and/or a composite film including any of the foregoing. In some embodiments, the tunnel insulating film 12 may include a thermal oxidation film. If the metal silicide nanocrystals (NC) are formed so as to be positioned in an upper portion of the charge storage insulating film 13′, the tunnel insulating film 12 can be omitted. In that case, a lower portion of the charge storage insulating film 13′ may perform a function similar to the function of the tunnel insulating film 12.

A blocking insulating film 17 can be positioned between the gate electrode 18 and the charge storage insulating film 13′. The blocking insulating film 17 may include a silicon oxide film, a silicon oxynitride film, a hafnium oxide film, an aluminium oxide film and/or a composite film including any of the foregoing.

The tunnel insulating film 12, the charge storage insulating film 13′, the blocking insulating film 17, and the gate electrode 18 form a gate pattern (G). An insulating spacer 19 can be positioned on sidewalls of the gate pattern (G).

N-type or p-type LDD regions 11a can be positioned in the substrate 10 adjacent to the gate pattern (G). A region between the LDD regions 11a is defined as a channel region. The source/drain regions 11b and 11b are positioned adjacent to the LDD regions 11a.

In a nonvolatile memory device as described above, metal silicide nanocrystals (NC) may have some properties similar to pure metal nanocrystals. Thus, the metal silicide nanocrystals may have a large capacitive coupling with the gate electrode 18 and/or the channel region. Therefore, an operation voltage for the device, such as a programming voltage and/or an erase voltage, can be lowered. In addition, metal silicide nanocrystals (NC) may have a good interface characteristic to the insulating film 13′ as compared to a pure metal nanocrystal. Furthermore, since the size of the metal silicide nanocrystals (NC) can be very small (e.g., in the order of about 2 nm to about 4 nm), the nonvolatile memory device can have very small features.

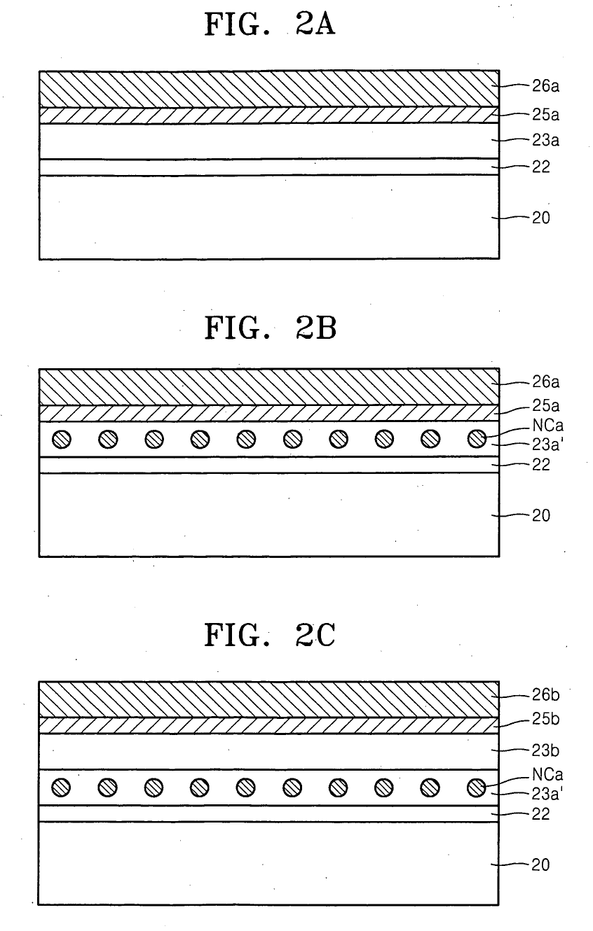

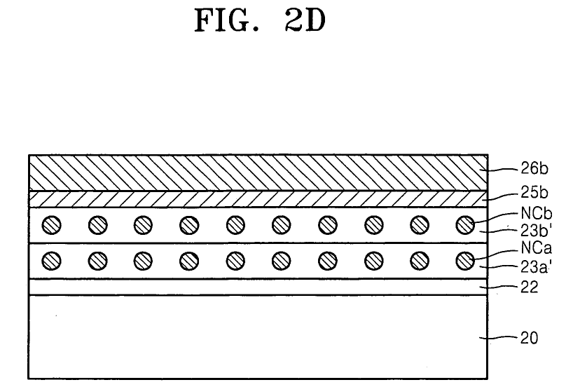

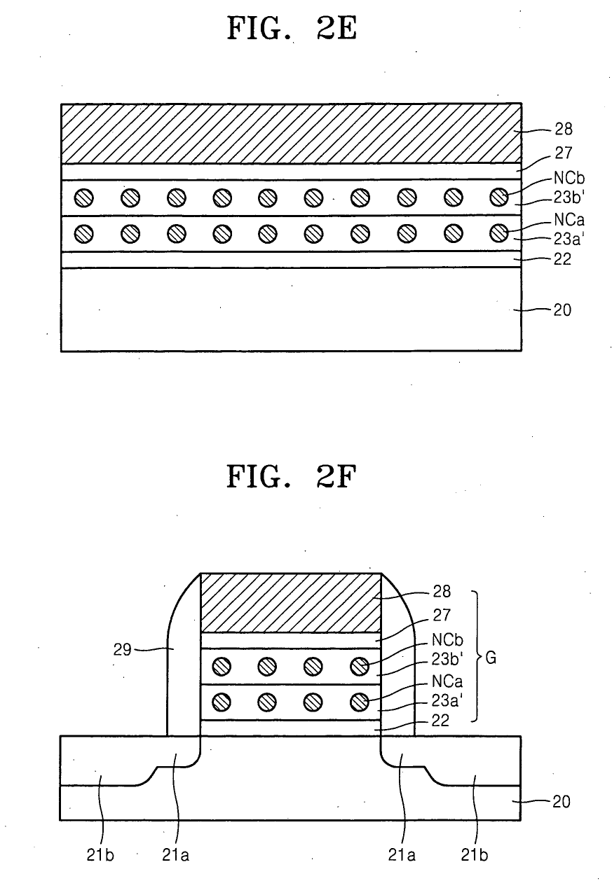

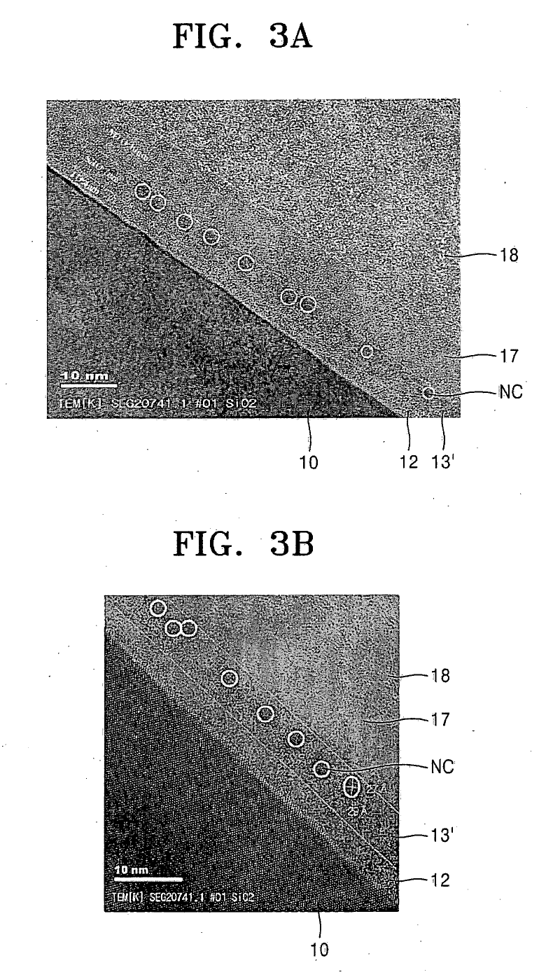

FIG. 2A through FIG. 2E are cross-sectional views illustrating methods of forming nonvolatile memory devices according to further embodiments of the present invention.

Referring to FIG. 2A, a tunnel insulating film 22 is stacked on a semiconductor substrate 20. The tunnel insulating film 22 may include a silicon oxide film, a silicon oxynitride film, a hafnium oxide film, an aluminium oxide film and/or a composite film including any of the foregoing. In some embodiments, the tunnel insulating film 22 may include a dry thermal oxidation film.

A first silicon-containing insulating film 23a is formed on the tunnel insulating film 22. The first silicon-containing insulating film 23a may be a silicon rich insulating film (SRI). The silicon rich insulating film may include a silicon rich oxide film (SRO) or a silicon rich nitride film (SRN). The first silicon-containing insulating film 23a may be formed to have a thickness of about 4 nm to about 10 nm.

A first metal film 25a is formed on the first silicon-containing insulating film 23a. The first metal film 25a may be a high-melting-point metal film, such as a tungsten (W) film, a titanium (Ti) film, a cobalt (Co) film, a nickel (Ni) film, a tantalum (Ta) film, a molybdenum (Mo) film and/or an alloy including any of the foregoing. In some embodiments, the first metal film 25a may include a cobalt (Co) film. The first metal film 25a may be formed to have a thickness of about 20 nm.

A first capping layer 26a is formed on the first metal film 25a. The first metal film 25a and the first capping layer 26a can be formed sequentially in situ without vacuum breaking. The first capping layer 26a may include a titanium film, a titanium nitride film and/or a composite film thereof.

Referring to FIG. 2B, the structure including the first capping layer 26a may be subjected to a low-temperature thermal treatment. As a result of the low-temperature thermal treatment, metal contained in the first metal film 25a diffuses into the first silicon-containing insulating film 23a, so as to be positioned in a portion of the first silicon-containing insulating film 23a. The low-temperature thermal treatment may be performed under an inert gas atmosphere, such as nitrogen, argon, and/or helium, at a temperature of about 300° C. to about 500° C.

After the low-temperature thermal treatment, the structure may be subjected to a high-temperature thermal treatment at a higher temperature than that of the low-temperature thermal treatment. As a result of the high-temperature thermal treatment, the metal that is diffused into the first silicon-containing insulating film 23a reacts with silicon particles in the silicon-containing insulating film 23 to thereby form first metal silicide nanocrystals (NCa). The high-temperature thermal treatment can be performed under an inert gas atmosphere, such as nitrogen, argon and/or helium, at a temperature of about 600° C. to about 800° C. The first silicon-containing insulating film 23a, which contains the first metal silicide nanocrystals (NCa), can be referred to as a first charge storage insulating film 23a′.

Referring to FIG. 2C, the first capping layer (as indicated at reference numeral 26a in FIG. 2B) and the first metal film (as indicated at reference numeral 25a in FIG. 2B) are removed to thereby expose the first charge storage insulating film 23a′.

A second silicon-containing insulating film 23b may be formed on the exposed first charge storage insulating film 23a′. The second silicon-containing insulating film 23b may also be a silicon rich insulating film, and more particularly, may include a silicon rich oxide film (SRO) and/or a silicon rich nitride film (SRN). However, the second silicon-containing insulating film 23b and the first silicon-containing insulating film 23a are not necessarily formed of the same materials. The second silicon-containing insulating film 23b may be formed to have a thickness of about 4 nm to about 10 nm.

A second metal film 25b is formed on the second silicon-containing insulating film 23b. The second metal film 25b may include a high-melting-point metal film, such as a tungsten (W) film, a titanium (Ti) film, a cobalt (Co) film, a nickel (Ni) film, a tantalum (Ta) film, a molybdenum (Mo) film or an alloy thereof, and need not include the same materials as the first metal film 25a. In some embodiments, the second metal film 25b may also include a cobalt (Co) film. The second metal film 25b may be formed to have a thickness of about 20 nm.

A second capping layer 26b is formed on the second metal film 25b. The second metal film 25b and the second capping layer 26b can be formed sequentially in situ without vacuum breaking. The second capping layer 26b may include a titanium film, a titanium nitride film and/or a composite thereof, and need not include the same materials as the first capping layer 26a.

Referring to FIG. 2D, the structure including the second capping layer 26b is subjected to a low-temperature thermal treatment to cause metal contained in the second metal film 25b to diffuse into the second silicon-containing insulating film 23b, so as to be positioned in a portion of the second silicon-containing insulating film 23b. The low-temperature thermal treatment can be performed under an inert gas atmosphere, such as nitrogen, argon and/or helium, at a temperature of about 300° C. to about 500° C.

After the low-temperature thermal treatment, the structure is subjected to high-temperature thermal treatment, causing the metal that is diffused into the second silicon-containing insulating film 23b to react with silicon particles in the second silicon-containing insulating film 23b and thereby form second metal suicide nanocrystals (NCb). The high-temperature thermal treatment can be performed under an inert gas atmosphere, such as nitrogen, argon and/or helium, at a temperature of about 600° C. to about 800° C. The second silicon-containing insulating film 23b, which contains the second metal silicide nanocrystals (NCb), can be referred to as a second charge storage insulating film 23b′.

Referring to FIG. 2E, the second capping layer (as indicated at reference numeral 26b in FIG. 2D) and the second metal film (as indicated at reference numeral 25b in FIG. 2D) are removed to thereby expose the second charge storage insulating film 23b′.

A blocking insulating film 27 is formed on the second charge storage insulating film 23b′. The blocking insulating film 27 may include a silicon oxide film, a silicon oxynitride film, a hafnium oxide film, an aluminium oxide film and/or a composite film including one or more of the foregoing. A gate conductive film 28 is formed on the blocking insulating film 27. The gate conductive film 28 may include a polysilicon film and/or a laminated film including polysilicon and metal silicide films.

Referring to FIG. 2F, the gate conductive film 28, the blocking insulating film 27, the second charge storage insulating film 23b′, the first charge storage insulating film 23a′ and the tunnel insulating film 22 may be sequentially patterned to thereby form a gate pattern (G).

N-type and/or p-type impurities may be implanted at low concentrations into the substrate 20 using the gate pattern (G) as a mask to form lightly doped drain (LDD) regions 21a. Thereafter, an insulating spacer 29 can be formed on sidewalls of the gate pattern (G), and impurities having the same conductivity as the impurities used to form the LDD regions 21a in the substrate 20 using the gate pattern (G) and the insulating spacer 29 as a mask are implanted at a higher concentration to thereby form source/drain regions 21b.

An example is presented below in order to facilitate understanding of the present invention. However, the example described below is provided only to facilitate the understanding of the present invention, and the present invention is not limited to example described below.

A semiconductor substrate was thermally oxidized so that a tunnel oxidation film having a thickness of about 4 nm was formed. A silicon rich oxide film having a thickness of 7 nm was formed on the tunnel oxidation film using atomic layer deposition. A cobalt film and a titanium nitride film having a thickness of 2 nm were formed on the silicon rich oxide film without vacuum breaking. Thereafter, the substrate was initially annealed at a temperature of about 460° C. under a nitrogen atmosphere for about 240 seconds, and subsequently annealed at a temperature of about 600° C. under a nitrogen atmosphere for about 240 seconds. The titanium nitride film and the cobalt film were sequentially removed to thereby expose the silicon rich oxide film, and thereafter a blocking oxide film having a thickness of 10 nm was formed on the silicon rich oxide film, and a gate conductive film was formed on the blocking oxide film. The gate conductive film, the blocking oxide film, the silicon rich oxide film, and the tunnel oxidation film were sequentially etched to thereby form the gate pattern.

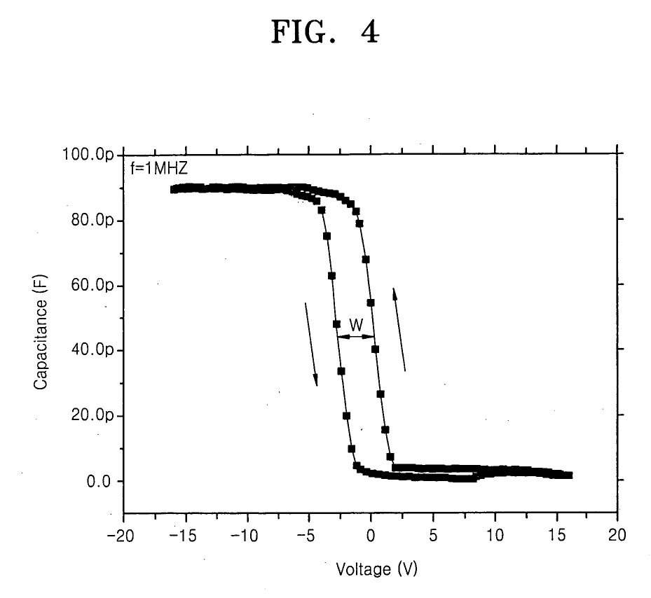

FIG. 3A is a transmission electron microscope (TEM) photograph of a gate pattern of a nonvolatile memory device according to some embodiments of the present invention, and FIG. 3B is an enlarged TEM photograph showing a portion of the structure shown in FIG. 3A.

Referring to FIG. 3A and FIG. 3B, cobalt silicide nanocrystals (NC, CoSi₂ nanocrystal) are positioned in an upper region of the silicon rich oxide film 13′. In addition, it will be appreciated that the size of the cobalt silicide nanocrystals (NC) is very small, on the order of about 3 nm in diameter. As described above, since the size of the nanocrystals is small, a width of the gate pattern can be very formed to be very small. Accordingly, a nonvolatile memory device having small feature sizes can be implemented.

FIG. 4 is a graph showing a C-V curve in a MOS capacitor structure of a nonvolatile memory device according to embodiments of the present invention.

Referring to FIG. 4, the capacitance of a MOS capacitor structure including a charge storage layer with CoSi₂ nanocrystals may form an approximately 3V window when the voltage is changed. Accordingly, it will be appreciated that the cobalt silicide nanocrystals formed in the silicon rich oxide film functions as a charge trapping site.

As described above, according to some embodiments of the present invention, a nonvolatile memory device including metal silicide nanocrystals can be formed. Since the metal silicide nanocrystals have characteristics similar to pure metal nanocrystals, a relatively large capacitive coupling with the gate electrode and channel region can be obtained, potentially resulting in lower device operation voltages. In addition, the size of the metal silicide nanocrystal can be very small, e.g. on the order of about 2 nm to about 4 nm, which may permit small nonvolatile memory device structures to be achieved.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A method of forming a nonvolatile memory device, comprising:
forming a silicon-containing insulating film on a substrate;
forming a metal film on the silicon-containing insulating film;
thermally treating the silicon-containing insulating film on which the metal film is formed to thereby form metal silicide nanocrystals in the silicon-containing insulating film;
removing the metal film to expose at least a portion of the silicon-containing insulating film; and
forming a gate electrode film on the exposed silicon-containing insulating film.

2. The method of claim 1, further comprising forming a tunnel insulating film on the substrate before forming the silicon-containing insulating film, wherein the silicon-containing insulating film is formed on the tunnel insulating film.

3. The method of claim 1, further comprising forming a blocking insulating film on the exposed portion of the silicon-containing insulating film before forming the gate electrode film, wherein the gate electrode film is formed on the blocking insulating film.

4. The method of claim 1, wherein thermally treating the silicon-containing insulating film comprises a low-temperature treatment and a high-temperature treatment.

5. The method of claim 4, wherein the low-temperature treatment is performed at a temperature of about 300° C. to about 500° C., and the high-temperature treatment is performed at a temperature of about 600° C. to about 800° C.

6. The method of claim 1, further comprising forming a capping layer on the metal film before thermally treating the silicon-containing insulating film.

7. The method of claim 1, wherein the silicon-containing insulating film comprises a first silicon-containing insulating film, the metal silicide nanocrystals comprise first metal silicide nanocrystals, and the metal film comprises a first metal film, the method further comprising:
before forming the gate electrode film:
forming a second silicon-containing insulating film on the first silicon-containing insulating film;
forming a second metal film on the second silicon-containing insulating film;
thermally treating the silicon-containing insulating film including the second metal film to thereby form second silicide nanocrystals in the second silicon-containing insulating film; and
removing the second metal film to expose at least portions of the second silicon-containing insulating film.

8. The method of claim 7, further comprising forming a capping layer on the second metal film before thermally treating the silicon-containing insulating film including the second metal film.

9. The method of claim 1, wherein the silicon-containing insulating film comprises a silicon rich oxide film (SRO) and/or a silicon rich nitride film (SRN).

10. The method of claim 1, wherein the metal film comprises tantalum, molybdenum, nickel, titanium, cobalt, and/or tungsten.

11. A method of forming metal silicide nanocrystals, comprising:
forming a silicon-containing insulating film on a substrate;
forming a metal film on the silicon-containing insulating film; and
thermally treating the silicon-containing insulating film including the metal film to thereby form metal silicide nanocrystals in the silicon-containing insulating film.

12. The method of claim 11, wherein thermally treating the silicon-containing insulating film comprises a low-temperature treatment and a high-temperature treatment.

13. The method of claim 12, wherein the low-temperature treatment is performed at a temperature of about 300° C. to about 500° C., and the high-temperature treatment is performed at a temperature of about 600° C. to about 800° C.

14. The method of claim 11, further comprising forming a capping layer on the metal film before thermally treating the substrate.

15. The method of claim 11, wherein the silicon-containing insulating film comprises a silicon rich oxide film and/or a silicon rich nitride film.

16. The method of claim 11, wherein the metal film comprises tantalum, molybdenum, nickel, titanium, cobalt, and/or tungsten.

17. A nonvolatile memory device, comprising:
a semiconductor substrate;
a charge storage insulating film that contains metal silicide nanocrystals on the semiconductor substrate; and
a gate electrode on the first charge storage insulating film.

18. The nonvolatile memory device of claim 17, further comprising a tunnel insulating film between the charge storage insulating film and the substrate.

19. The nonvolatile memory device of claim 17, further comprising a blocking insulating film between the gate electrode and the charge storage insulating film.

20. The nonvolatile memory device of claim 17, wherein the charge storage insulating film comprises a first charge storage insulating film and wherein the metal silicide nanocrystals comprise first metal silicide nanocrystals, the device further comprising a second charge storage insulating film containing second metal suicide nanocrystals between the gate electrode and the first charge storage insulating film.

21. The nonvolatile memory device of claim 17, wherein the charge storage insulating film comprises a silicon rich oxide film and/or a silicon rich nitride film.

22. The nonvolatile memory device of claim 17, wherein the metal silicide comprises tantalum silicide, molybdenum silicide, nickel silicide, titanium silicide, cobalt silicide, and/or tungsten silicide.
